(19) United States
(12) Patent Application Publication
(10) Pub. No.: US 2006/0065811 A1
(43) Pub. Date: Mar. 30, 2006

(54) Wide dynamic range CMOS image sensor having controllabale photo-response characteristic and control method thereof

(76) Inventors: Hongil Yoon, Yongin-Si (KR); Hyun Yoon, Anyang-Si (KR); Yong Lim, Suwon-Si (KR)

Correspondence Address: Peter T. Kwon;GWiPS, Kangnam P.O. Box 2301, Seoul, 135-242, KR

(21) Appl. No.: 10/949,327

(22) Filed: Sep. 27, 2004

(51) Int. Cl. H01L 27/00

(52) U.S. Cl. 250/208.1

(57) ABSTRACT

A wide dynamic range CMOS image sensor is invented for easily changing a photo-response characteristic between a linear response and a logarithmic response without altering any hardware. A method of controlling the photo-response characteristic is also provided in which: the reset signal generator of the CMOS image sensor sets the maximum value of a reset pulse to V_{DD} and the minimum value of the reset pulse to ΔV which is greater than V_{SS}, such that the active pixel can have a photo-response characteristic that combines a linear response and a logarithmic response. When the ΔV value is varied in the reset pulse generated from the reset signal generator, the boundary between the linear response and the logarithmic response of the image sensor can be adjusted.

### BACKGROUND OF THE INVENTION

1. Field of the Invention

The present invention relates to a wide dynamic range CMOS image sensor that can easily change its photo-response characteristic between a linear response and a logarithmic response without altering any hardware, and a method of controlling the photo-response characteristic.

2. Related Prior Art

A CMOS image sensor, which is a kind of opto-electronic device, is an element in which photo charges generated by light are accumulated in a capacitor of a photo diode so as to output a linear voltage as a response to light. The CMOS image sensor is widely used in various image recognition devices such as a small-sized camera, a fingerprint recognition device or the like.

In general, the dynamic range of the CMOS image sensor for perceiving light is 60 dB, which is much smaller than the dynamic range of human beings for perceiving light, i.e., about 90 dB. This means that when a high-contrast image containing both dark and bright regions is photographed, image distortion occurs.

FIG. 1 shows a circuit diagram extracted from a paper entitled “Wide-Dynamic-Range Pixel with Combined Linear and Logarithmic Response and Increased Signal Swing”, Eric C.

Fox, Jerry Hynecek, and Douglas R. Dykaar, DALSA Inc., Pro. SPIE International Symposium, Opt. Eng. 3965, pp. 4-10, May 2000. As shown in FIG. 1, the pixel has a structure of providing a wide dynamic range for perceiving light by allowing a voltage VOC to have a photo-response characteristic that combines a linear and logarithmic response. An image sensor with such a photo-response characteristic has been proposed in a web site (http://www.photonfocus.com/html/eng/cmos/linlog.php) and a paper entitled “Smart Pixel”, Seitz, P., 2001 International Symposium on Electron Devices for Microwave and Optoelectronic Application, 15-16, pp. 229-234, November 2001.

The pixel of an image sensor has a more excellent response characteristic and can be arranged in higher densities as the “fill factor” (the ratio of the area occupied by a light-receiving section of a photo diode to the total pixel areas) becomes greater. Thus, such a pixel can implement high resolution. However, the conventional pixel structure having a combined linear and logarithmic photo-response characteristic requires one additional transistor and one additional bias voltage supply line therein, as compared to the conventional linear response pixel.

That pixel has a disadvantage in that it has a smaller fill factor in the case of implementing a pixel structure with the same transistor-to-bias voltage supply line area ratio to which one transistor and one bias voltage supply line are added, as compared with the conventional pixel structure [“CMOS image sensors: electronic camera-on-a-chip”, Eric R. Fossum. IEEE Transactions on Electron Devices, Volume.44, Issue 10, pp. 1689-1698, October 1997] having a linear response, which uses three transistors as shown in FIG. 2.

In addition, in order for the conventional pixel to have a photo-response characteristic that combines a linear and logarithmic response, a voltage V_{bias} should be higher than a voltage V_{DD}, and in order to widen the width of a linear response, a difference in voltage between V_{bias} and V_{DD} should be great, which requires additional installation of separate circuit means for generating a higher voltage than V_{DD}. This results in the application of stress to a relevant transistor, which contributes to degradation in performance and reliability.

### SUMMARY OF THE INVENTION

Therefore, the present invention has been made in view of the above problems, and it is an object of the present invention to provide a wide dynamic range CMOS image sensor which can implement a photo-response characteristic that combines a linear response and a logarithmic response only by varying the reset signal without the need for installing a separate hardware or element in a pixel thereof and which can control the photo-response characteristic, and a method of controlling the photo-response characteristic.

To accomplish the above objects, according to the present invention, there is provided a wide dynamic range CMOS image sensor comprising an active pixel which includes a photo diode and a transistor and to which a reset pulse is applied from a reset signal generator, wherein the reset signal generator sets the maximum value of the reset pulse to V_{DD} and the minimum value of the reset pulse to ΔV which is greater than V_{SS}, thereby allowing the active pixel to have a photo-response characteristic that combines a linear response and a logarithmic response.

According to the wide dynamic range CMOS image sensor of the present invention, a pixel having a photo-response characteristic that combines a linear and a logarithmic response has the same structure as a conventional active pixel except for the replacement of the reset pulse.

That is, the reset signal generator of the CMOS image sensor according to the present invention sets the maximum value of a reset pulse to V_{DD} and the minimum value of the reset pulse to ΔV which is greater than V_{SS}, such that the active pixel can have a photo-response characteristic that combines a linear response and a logarithmic response. When the ΔV value is varied in the reset pulse generated from the reset signal generator, the boundary between the linear response and the logarithmic response of the image sensor can be adjusted.

### BRIEF DESCRIPTION OF THE DRAWINGS

The above and other objects, features and advantages of the present invention will be apparent from the following detailed description of the preferred embodiments of the invention in conjunction with the accompanying drawings, in which:

FIG. 1 is a circuit diagram illustrating an equivalent circuit of a pixel having a photo-response characteristic that combines a linear and logarithmic response according to the prior art.

FIG.2 is a circuit diagram illustrating an equivalent circuit of a linear response circuit according to the prior art.

FIGS. 3a and 3b are a circuit diagram illustrating a circuit for representing pixels of an image sensor and a waveform diagram showing a control signal for the image sensor according to the present invention.

FIGS. 4a and 4b are graphs illustrating the results of a simulated test of a response characteristic according to the control method of the present invention.

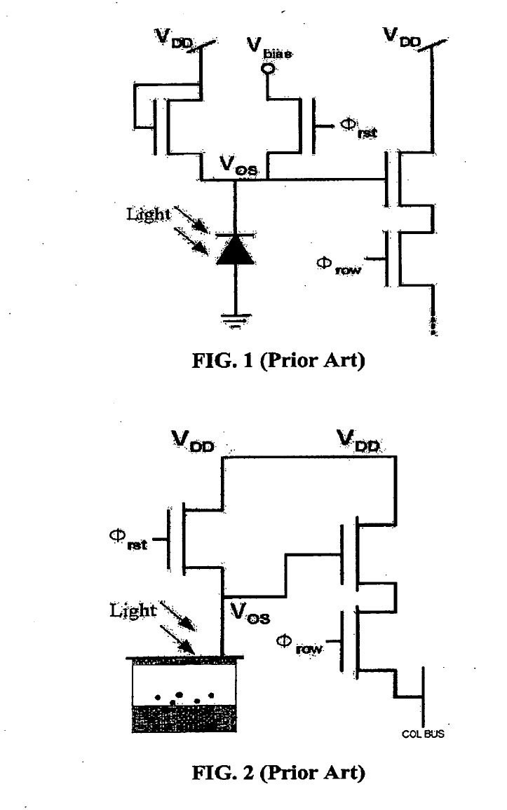

### DETAILED DESCRIPTION OF THE PREFERRED EMBODIMENT

Reference will now be made in detail to the preferred embodiment of the present invention with reference to the attached drawings.

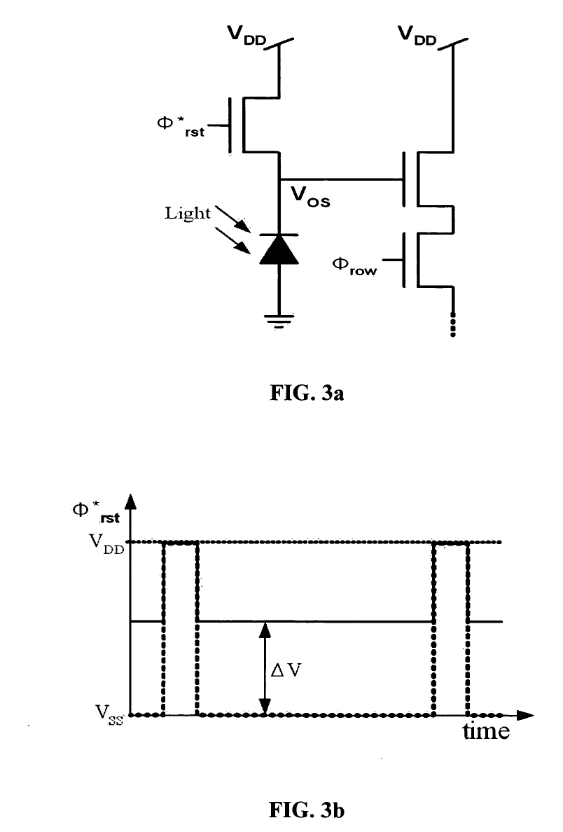

Referring to the drawings, a conventional reset signal Φrst is a pulse waveform signal having V_{DD} and V_{SS} that vary over time according to the dotted line shown in FIG. 3b. On the other hand, the maximum value of a drive signal Φ*rst for obtaining a linear and logarithmic response is set to have the same V_{DD} as in the conventional reset signal Φrst, but the minimum value of the drive signal Φ*rst is equal to the a difference between ΔV and V_{SS}.

The value ΔV has a voltage between V_{DD} and V_{SS}, and the boundary between the linear response and the logarithmic response can be adjusted depending on the value of ΔV. If ΔV is identical to V_{SS}, the pixel according to the current invention is driven in the same manner as the conventional pixel with a linear response characteristic using three transistors. If, on the other hand, ΔV is identical to V_{DD}, the pixel according to the current invention is driven in the same manner as the conventional pixel with a basic logarithmic response characteristic.

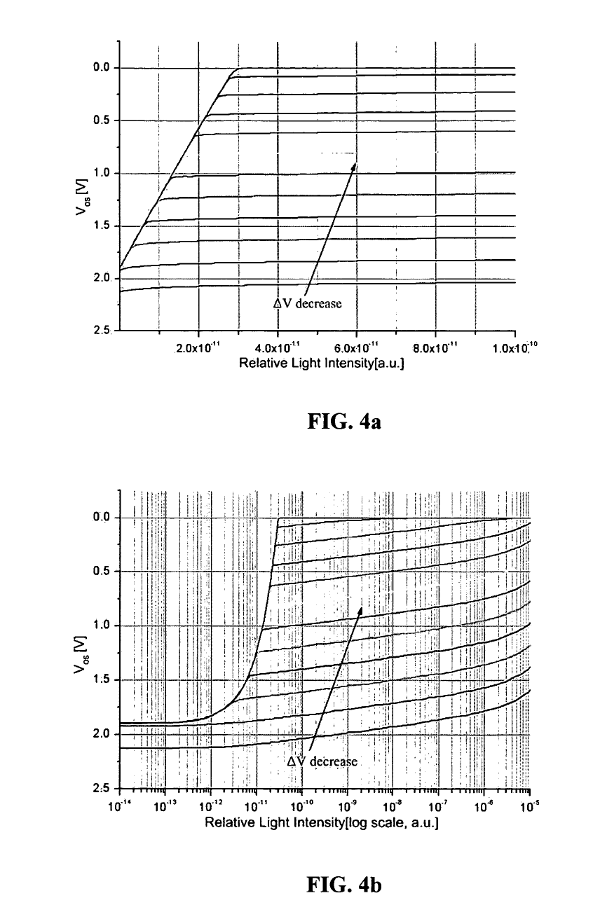

In the meantime, as shown in FIGS. 4a and 4b, when ΔV has a voltage value between V_{DD} and V_{SS}, the pixel according to the current invention has a wide dynamic range photo-response characteristic that combines a linear and logarithmic response. As the value of ΔV is decreased, the width of the linear response becomes larger. That is, controlling the value of ΔV adjusts the boundary between the linear response and the logarithmic response.

In the case where the pixel having a wide dynamic range photo-response characteristic that combines a linear and logarithmic response is implemented using the above manner, the pixel according to the current invention can obtain a higher fill factor since one transistor and one bias voltage supply line is omitted as compared with the conventional pixel structure. Furthermore, the pixel according to the current invention does not require a higher voltage than V_{DD}, thereby ensuring the enhanced lifespan of the pixel and reducing the degradation in performance of the pixel.

The embodiment described above is merely an illustrative example for concretely explaining the spirit of the present invention as one of various embodiments of the invention. The conventional active pixel structure using four transistors can also obtain the same photo-response characteristic as the present invention using a variation of the reset signal according to the present invention.

As described above, according to the present invention, the dynamic range of the CMOS image sensor can be easily widened in spite of the use of the conventional pixel structure. Moreover, the image sensor according to the current invention makes it possible to fabricate smaller pixels since the fill factor of its pixel is relatively high as compared with the conventional pixel with a wide dynamic range photo-response characteristic. Therefore, since the ratio of the pixel area of the image sensor according to the current invention to the pixel area of the conventional image sensor based on the same resolution is small, production efficiency can be improved. In addition, an image sensor of high resolution can be fabricated using silicon of the same area.

While the present invention has been described with reference to the particular illustrative embodiments, it is not to be restricted by the embodiments but only by the appended claims. It is to be appreciated that those skilled in the art can change or modify the embodiments without departing from the scope and spirit of the present invention.

1-4. (canceled)

5. A method for controlling a photoresponse characteristic of a wide dynamic range CMOS image sensor comprising an active pixel including a photo diode, a transistor and a reset signal generator for setting a reset pulse, the method comprising the steps of:
setting maximum value of a reset pulse applied to an active pixel to V_{DD} (high supply voltage), and
setting the minimum value of a reset pulse equal to V (offset voltage) which is greater than V_{SS} (low supply voltage),
thereby the active pixel has a photo-response characteristic that combines a linear response and a logarithmic response.
